(19) United States
(12) Patent Application Publication
(10) Pub. No.: US 2025/0003068 A1
(43) Pub. Date: Jan. 2, 2025

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventors: Kazuyuki OKUDA, Toyama (JP); Tomoki IMAMURA, Toyama (JP); Takaaki NODA, Toyama (JP); Masato TERASAKI, Toyama (JP)

(21) Appl. No.: 18/882,248

(22) Filed: Sep. 11, 2024

Related U.S. Application Data
(63) Continuation of application No. PCT/JP2022/034286, filed on Sep. 13, 2022.

(30) Foreign Application Priority Data
Mar. 16, 2022 (JP) 2022-041115

(51) Int. Cl. C23C 16/455; C23C 16/34; C23C 16/52; C23C 16/56; H01J 37/32; H01L 21/02

(52) U.S. Cl. CPC C23C 16/45538; C23C 16/345; C23C 16/45544; C23C 16/52; C23C 16/56; H01J 37/32449; H01L 21/0217; H01L 21/02274; H01L 21/0228

(57) ABSTRACT

There is provided a technique that includes: forming a film containing an element and nitrogen on a substrate by performing a cycle including: (a) forming a first layer by supplying a source gas containing the element and a halogen element to the substrate; (b) generating a first active species by plasma-exciting and supplying an elemental gas containing the first active species to the substrate; and (c) forming a second layer by generating a second active species by plasma-exciting a reactive gas containing nitrogen and supplying the reactive gas containing the second active species to the substrate, wherein (b) includes generating a third active species by plasma-exciting and supplying a compound gas containing the third active species to the substrate, and a ratio of a supply amount of the compound gas to that of the elemental gas is set to be lower than ½ in (b).

### CROSS REFERENCE TO RELATED APPLICATIONS

This application is a bypass continuation application of PCT International Application No. PCT/JP2022/034286, filed on Sep. 13, 2022, in the WIPO, the international application being based upon and claiming the benefit of priority from Japanese Patent Application No. 2022-041115, filed on Mar. 16, 2022, in the Japanese Patent Office, the entire contents of which are hereby incorporated by reference.

### TECHNICAL FIELD

The present disclosure relates to a substrate processing method, a method of manufacturing a semiconductor device, a non-transitory computer-readable recording medium and a substrate processing apparatus.

### BACKGROUND

According to some related arts, as a part of a manufacturing process of a semiconductor device, a step of forming a film on a substrate by alternately supplying a source gas and a reactive gas to the substrate may be performed.

### SUMMARY

According to the present disclosure, there is provided a technique capable of forming a film on a substrate, wherein a uniformity of properties of the film is excellent within a surface of the substrate.

According to an embodiment of the present disclosure, there is provided a technique that includes: forming a film containing a predetermined element and nitrogen on a substrate by performing a cycle a predetermined number of times, wherein the cycle includes: (a) forming a first layer by supplying a source gas containing the predetermined element and a halogen element to the substrate; (b) generating a first active species by plasma-exciting an elemental gas constituted by a single element and supplying the elemental gas containing the first active species to the substrate; and (c) forming a second layer by generating a second active species by plasma-exciting a reactive gas containing nitrogen and supplying the reactive gas containing the second active species to the substrate, wherein (b) includes generating a third active species by plasma-exciting a compound gas constituted by a plurality of elements and supplying the compound gas containing the third active species to the substrate, and wherein, in (b), a ratio of a supply amount of the compound gas to a supply amount of the elemental gas is set to be lower than ½.

### BRIEF DESCRIPTION OF THE DRAWINGS

FIG. 1 is a diagram schematically illustrating a vertical cross-section of a vertical type process furnace of a substrate processing apparatus preferably used in one or more embodiments of the present disclosure.

FIG. 2 is a diagram schematically illustrating a horizontal cross-section, taken along a line A-A shown in FIG. 1, of the vertical type process furnace of the substrate processing apparatus preferably used in the embodiments of the present disclosure.

FIG. 3 is a block diagram schematically illustrating a configuration of a controller and related components of the substrate processing apparatus preferably used in the embodiments of the present disclosure.

FIG. 4 is a diagram schematically illustrating an example of supply timings of gases and a supply timing of an RF power in a film forming sequence according to the embodiments of the present disclosure.

FIG. 5 is a diagram schematically illustrating examples of the film forming sequence in an example of the embodiments of the present disclosure.

FIG. 6 is a diagram schematically illustrating measurement results of a wet etching rate of a film formed in the example of the embodiments of the present disclosure.

FIG. 7 is a diagram schematically illustrating a relationship between the wet etching rate and a chlorine concentration of the film formed in the example of the embodiments of the present disclosure.

### DETAILED DESCRIPTION

### Embodiments of Present Disclosure

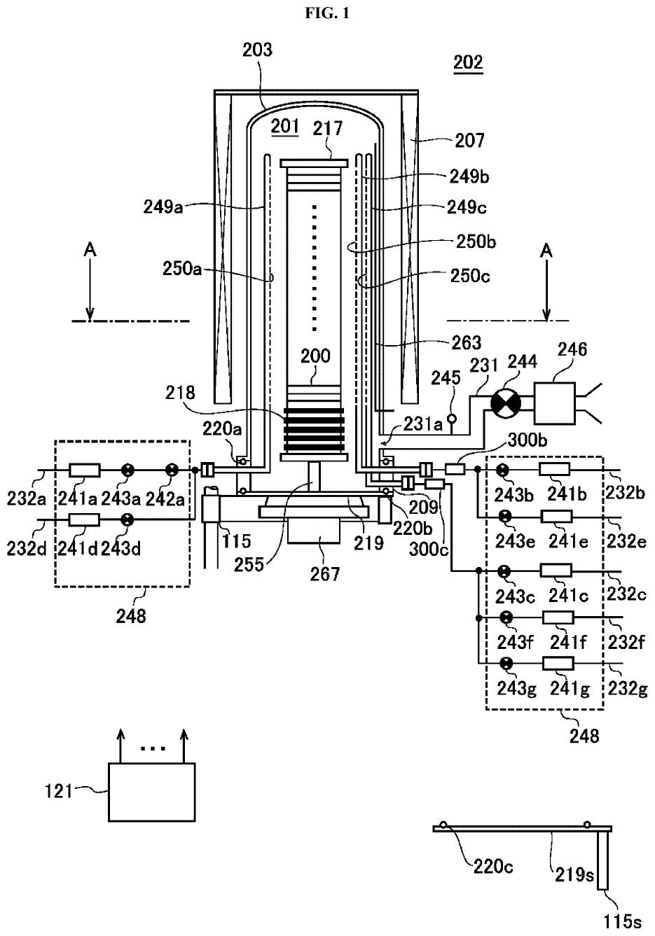

Hereinafter, one or more embodiments (also simply referred to as “embodiments”) of the technique of the present disclosure will be described in detail mainly with reference to FIGS. 1 to 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

As shown in FIG. 1, a substrate processing apparatus according to the present embodiments includes a vertical type process furnace (also simply referred to as a “process furnace”) 202. The process furnace 202 includes a heater 207 serving as a heating structure or a heating apparatus. The heater 207 is of a cylindrical shape, and is vertically installed while being supported by a support plate (not shown). The heater 207 also functions as an activator (also referred to as a “thermal exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”. The wafer 200 is processed in the process chamber 201, that is, in the process vessel.

Nozzles 249a, 249b and 249c are provided in the process chamber 201 so as to penetrate a side wall of the manifold 209. The nozzle 249a serves as a first supplier (which is a first supply structure), the nozzle 249b serves as a second supplier (which is a second supply structure) and the nozzle 249c serves as a third supplier (which is a third supply structure). The nozzles 249a, 249b and 249c may also be referred to as a first nozzle 249a, a second nozzle 249b and a third nozzle 249c, respectively. For example, each of the nozzles 249a, 249b and 249c is made of a heat resistant material such as quartz and silicon carbide (SiC). Gas supply pipes 232a, 232b and 232c are connected to the nozzles 249a, 249b and 249c, respectively. The gas supply pipes 232a, 232b and 232c may also be referred to as a first gas supply pipe R1, a second gas supply pipe R2 and a third gas supply pipe R3, respectively.

A mass flow controller (also simply referred to as an “MFC”) 241a and valves 243a and 242a serving as opening/closing valves are sequentially installed at the gas supply pipe 232a in this order from an upstream side to a downstream side of the gas supply pipe 232a in a gas flow direction. A gas supply pipe 232d is connected to the gas supply pipe 232a at a downstream side of the valve 242a. An MFC 241d and a valve 243d serving as an opening/closing valve are sequentially installed at the gas supply pipe 232d in this order from an upstream side to a downstream side of the gas supply pipe 232d in the gas flow direction.

MFCs 241b and 241c serving as flow rate controllers (flow rate control structures) and valves 243b and 243c serving as opening/closing valves are sequentially installed at the gas supply pipes 232b and 232c, respectively, in this order from upstream sides to downstream sides of the gas supply pipes 232b and 232c in the gas flow direction. A gas supply pipe 232c is connected to the gas supply pipe 232b at a downstream side of the valve 243b. Gas supply pipes 232f and 232g are connected to the gas supply pipe 232c at a downstream side of the valve 243c. MFCs 241c, 241f and 241g and valves 243e, 243f and 243g are sequentially installed at the gas supply pipes 232c, 232f and 232g, respectively, in this order from upstream sides to downstream sides of the gas supply pipes 232e, 232f and 232g in the gas flow direction. For example, each of the gas supply pipes 232a to 232g is made of a metal material such as stainless steel (SUS).

Remote plasma units 300b and 300c serving as exciters (which are plasma exciters or plasma activators) configured to activate (or excite) the gas with a plasma are installed at downstream sides of the valves 243b and 243c of the gas supply pipes 232b and 232c, respectively.

For example, two electrodes (not shown) for generating the plasma are provided inside each of the remote plasma units 300b and 300c. By applying a power between the two electrodes mentioned above, it is possible to excite the gas into a plasma state inside the remote plasma units 300b and 300c, that is, it is possible to plasma-excite the gas. Hereinafter, such an act of exciting the gas into the plasma state may also be simply referred to as a “plasma excitation”. By applying the power, that is, a high frequency power (RF power), to the electrodes mentioned above, the gas excited into the plasma state inside the remote plasma units 300b and 300c can be supplied into the process chamber 201 via the gas supply pipes 232b and 232c and the nozzles 249b and 249c. Further, a first buffer chamber (buffer structure) in which the nozzle 249b and a first plasma generation electrode described later can be accommodated may be provided inside or outside the reaction tube 203 along a wall surface of the reaction tube 203. In such a case, the remote plasma unit configured to plasma-excite the gas supplied through the nozzle 249b may be constituted by the first buffer chamber and the first plasma generation electrode. Similarly, a second buffer chamber in which the nozzle 249c and a second plasma generation electrode described later can be accommodated may be provided inside or outside the reaction tube 203 along the wall surface of the reaction tube 203. In such a case, the remote plasma unit configured to plasma-excite the gas supplied through the nozzle 249c may be constituted by the second buffer chamber and the second plasma generation electrode. In addition, the first buffer chamber and the second buffer chamber may be configured as a common buffer chamber, and the first plasma generation electrode and the second plasma generation electrode may be configured as a common plasma generation electrode.

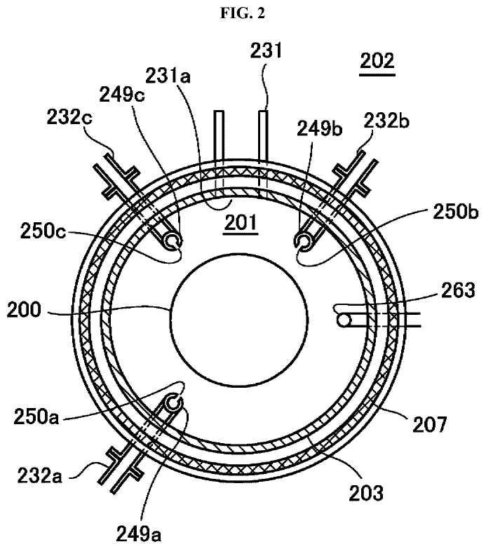

As shown in FIGS. 1 and 2, each of the nozzles 249a to 249c is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along an arrangement direction of the wafers 200). That is, each of the nozzles 249a to 249c is installed in a region that is located beside and horizontally surrounds a wafer arrangement region in which the wafers 200 are arranged (stacked) along the wafer arrangement region.

The nozzle 249a is disposed farther from an exhaust port 231a described later than the nozzles 249b and 249c. That is, the nozzles 249b and 249c are disposed closer to the exhaust port 231a than the nozzle 249a. Further, when viewed from above, the nozzles 249b and 249c are disposed symmetrically (line symmetrically) with respect to a line passing through a center of the wafer 200 loaded (transferred) into the process chamber 201, that is, a line passing through a center of the reaction tube 203 and a center of the exhaust port 231a. In addition, the nozzles 249a and 249b are disposed to face each other with respect to the line passing through the center of the reaction tube 203 and the center of the exhaust port 231a.

A plurality of gas supply holes 250a, a plurality of gas supply holes 250b and a plurality of gas supply holes 250c are provided at side surfaces of the nozzles 249a, 249b and 249c, respectively. Gases are supplied via the gas supply holes 250a, the gas supply holes 250b and the gas supply holes 250c, respectively. The gas supply holes 250a, the gas supply holes 250b and the gas supply holes 250c are open to face the center of reaction tube 203, and are configured such that the gases are supplied toward the wafers 200 via the gas supply holes 250a, the gas supply holes 250b and the gas supply holes 250c, respectively. The gas supply holes 250a and the gas supply holes 250b are open to face each other (or opposite to each other) with respect to the line passing through the center of the wafer 200, that is, the line passing through the center of the reaction tube 203 and the center of the exhaust port 231a. The gas supply holes 250a, the gas supply holes 250b and the gas supply holes 250c are provided from the lower portion toward the upper portion of the reaction tube 203.

A gas containing a predetermined element and a halogen element (which serves as a source gas) is supplied into the process chamber 201 through the gas supply pipe 232a provided with the MFC 241a, the valve 243a, the valve 242a and the nozzle 249a.

A gas constituted by a single element (hereinafter also referred to as an elemental gas or a single substance gas) is supplied into the process chamber 201 through the gas supply pipe 232b provided with the MFC 241b and the valve 243b and the nozzle 249b.

A gas containing nitrogen (N) (which serves as a reactive gas) is supplied into the process chamber 201 through the gas supply pipe 232c provided with the MFC 241c and the valve 243c and the nozzle 249c.

A gas constituted by a plurality of elements (which serves as a compound gas) is supplied into the process chamber 201 through the gas supply pipe 232f provided with the MFC 241f and the valve 243f, the gas supply pipe 232c and the nozzle 249c. The present embodiments are described by way of an example in which the elemental gas and the compound gas are supplied through the nozzle 249b and the nozzle 249c, respectively. However, the elemental gas and the compound gas may be supplied through the same nozzle. Further, the present embodiments are described by way of an example in which the elemental gas and the reactive gas are supplied through the nozzle 249b and the nozzle 249c, respectively. However, the elemental gas and the reactive gas may be supplied through the same nozzle. In addition, for example, the elemental gas, the reactive gas and the compound gas may be supplied through a single nozzle (for example, one of the nozzles 249b and 249c).

An inert gas is supplied into the process chamber 201 via the gas supply pipes 232d, 232e and 232g provided with the MFCs 241d, 241e and 241g and the valves 243d, 243c and 243g, respectively, the gas supply pipes 232a to 232c and the nozzles 249a to 249c. For example, the inert gas may act as a purge gas, a carrier gas, a dilution gas and the like.

A source gas supplier (which is a source gas supply structure or a source gas supply system) is constituted mainly by the gas supply pipe 232a, the MFC 241a, the valves 243a and 242a and a gas storage described later. A reactive gas supplier (which is a reactive gas supply structure or a reactive gas supply system) is constituted mainly by the gas supply pipe 232c, the MFC 241c and the valve 243c. An elemental gas supplier (which is an elemental gas supply structure or an elemental gas supply system) is constituted mainly by the gas supply pipe 232b, the MFC 241b and the valve 243b. A compound gas supplier (which is a compound gas supply structure or a compound gas supply system) is constituted mainly by the gas supply pipe 232f, the MFC 241f and the valve 243f. Further, an inert gas supplier (which is an inert gas supply structure or an inert gas supply system) is constituted mainly by the gas supply pipes 232d, 232c and 232g, the MFCs 241d, 241e and 241g and the valves 243d, 243c and 243g.

Any one or the entirety of the gas suppliers described above may be embodied as an integrated gas supply system 248 in which the components such as the valves 243a to 243g, the gas storage and the MFCs 241a to 241g are integrated. The integrated gas supply system 248 is connected to each of the gas supply pipes 232a to 232g. An operation of the integrated gas supply system 248 to supply various gases to the gas supply pipes 232a to 232g, for example, operations such as an operation of opening and closing the valves 243a to 243g and an operation of adjusting flow rates of the gases by the MFCs 241a to 241g may be controlled by a controller 121 which will be described later. The integrated gas supply system 248 may be embodied as an integrated structure (integrated unit) of an all-in-one type or a divided type. The integrated gas supply system 248 may be attached to or detached from the components such as the gas supply pipes 232a to 232f on a basis of the integrated structure. Operations such as maintenance, replacement and addition for the integrated gas supply system 248 may be performed on a basis of the integrated structure.

The exhaust port 231a through which an inner atmosphere of the process chamber 201 is exhausted is provided at a lower side wall of the reaction tube 203. The exhaust port 231a may be provided so as to extend upward from the lower portion toward the upper portion of the reaction tube 203 along a side wall of the reaction tube 203 (that is, along the wafer arrangement region). An exhaust pipe 231 is connected to the exhaust port 231a. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) configured to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation for the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly scaling (or closing) a lower end opening of the manifold 209 is provided under the manifold 209. For example, the seal cap 219 is made of a metal material such as stainless steel, and is of a disk shape. An O-ring 220b serving as a seal is provided on an upper surface of the seal cap 219 so as to be in contact with the lower end of the manifold 209. A rotator 267 configured to rotate a boat 217 described later is provided under the seal cap 219. For example, a rotating shaft 255 of the rotator 267 is made of a metal material such as stainless steel, and is connected to the boat 217 through the seal cap 219. As the rotator 267 rotates the boat 217, the wafers 200 accommodated in the boat 217 are rotated. The seal cap 219 is elevated or lowered in the vertical direction by a boat elevator 115 serving as an elevating structure provided outside the reaction tube 203. The boat elevator 115 serves as a transfer device (which is a transfer structure or a transfer system) capable of transferring (loading) the boat 217 and the wafers 200 accommodated therein into the process chamber 201 and capable of transferring (unloading) the boat 217 and the wafers 200 accommodated therein out of the process chamber 201 by elevating and lowering the seal cap 219.

A shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as stainless steel, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 (which serves as a substrate support or a substrate retainer) is configured such that the wafers 200 (for example, 25 wafers to 200 wafers) are accommodated (or supported) in the vertical direction in the boat 217 while the wafers 200 are horizontally oriented with their centers aligned with one another in a multistage manner. That is, the boat 217 is configured such that the wafers 200 are arranged in the vertical direction in the boat 217 while the wafers 200 are horizontally oriented with a predetermined interval therebetween. For example, the boat 217 is made of a heat resistant material such as quartz and SiC. For example, a plurality of heat insulation plates 218 made of a heat resistant material such as quartz and SiC are supported at a lower portion of the boat 217 in a multistage manner. The boat 217 is configured to be capable of supporting each of the wafers 200.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along the inner wall of the reaction tube 203.

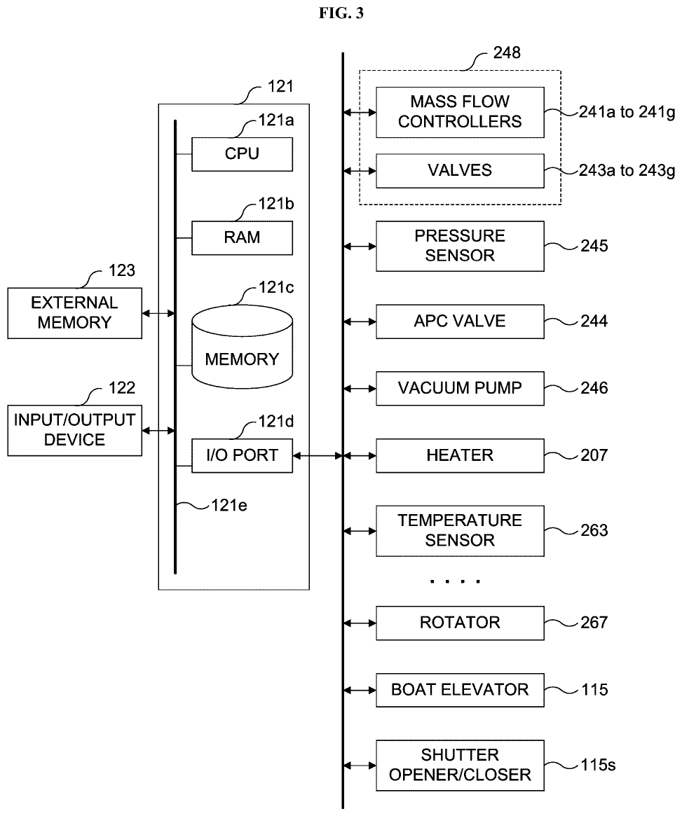

As shown in FIG. 3, the controller 121 serving as a control structure (control apparatus) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d may exchange data with the CPU 121a through an internal bus 121c. For example, an input/output device 122 constituted by a component such as a touch panel is connected to the controller 121. Further, the controller 121 is configured to be capable of being connected to an external memory 123.

For example, the memory 121c is configured by a component such as a flash memory, a hard disk drive (HDD) and a solid state drive (SSD). For example, a control program configured to control an operation of a film forming apparatus (that is, the substrate processing apparatus) and a process recipe containing information on sequences and conditions of a processing (substrate processing) described later may be readably stored in the memory 121c. The process recipe is obtained by combining steps (sequences or processes) of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a to 241g, the valves 243a to 243g, the pressure sensor 245, the APC valve 244, the vacuum pump 246, the temperature sensor 263, the heater 207, the rotator 267, the boat elevator 115 and the shutter opener/closer 115s.

The CPU 121a is configured to read the control program from the memory 121c and execute the read control program. In addition, the CPU 121a is configured to read the recipe from the memory 121c, for example, in accordance with an operation command inputted from the input/output device 122. In accordance with contents of the read recipe, the CPU 121a may be configured to be capable of controlling various operations such as flow rate adjusting operations for various gases by the MFCs 241a to 241g, opening and closing operations of the valves 243a to 243g, an opening and closing operation of the APC valve 244, a pressure regulating operation (pressure adjusting operation) by the APC valve 244 based on the pressure sensor 245, a start and stop operation of the vacuum pump 246, a temperature regulating operation (temperature adjusting operation) by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of the shutter 219s by the shutter opener/closer 115s.

The controller 121 may be embodied by installing the above-described program stored in the external memory 123 into the computer. For example, the external memory 123 may include a magnetic disk such as the HDD, an optical disk such as a CD, a magneto-optical disk such as an MO and a semiconductor memory such as a USB memory and the SSD. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication interface such as the Internet and a dedicated line may be used for providing the program to the computer.

### (2) Substrate Processing

Hereinafter, an example of a process sequence (that is, a film forming sequence) of the substrate processing of forming a film (which contains the predetermined element and nitrogen (N)) on the wafer 200 serving as the substrate will be described. The substrate processing (which is a part of a manufacturing process of a semiconductor device) is performed by using the substrate processing apparatus described above. In the following descriptions, operations of components constituting the substrate processing apparatus are controlled by the controller 121.

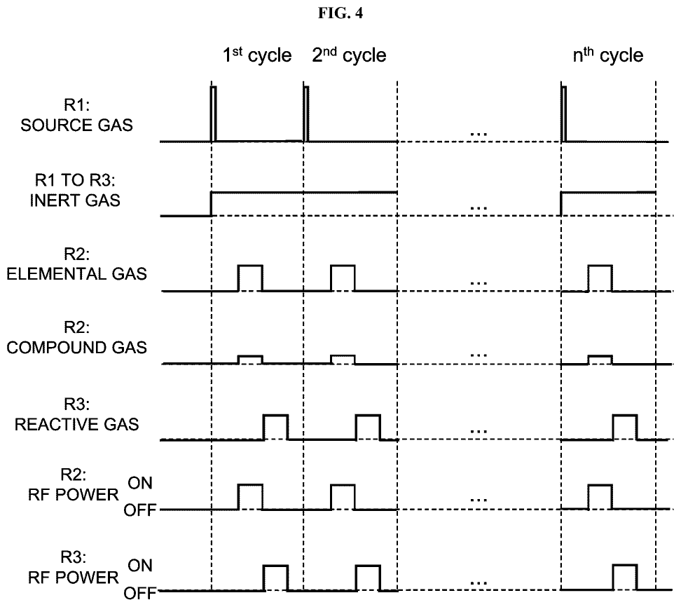

According to the film forming sequence of the present embodiments, as shown in FIG. 4, the film containing the predetermined element and nitrogen (N) is formed on the wafer 200 by performing a cycle a predetermined number of times (n times, where n is an integer of 1 or more). The cycle may include: (a) forming a first layer by supplying the source gas containing the predetermined element and the halogen element to the wafer 200; (b) generating an active species X (also referred to as a first active species) by plasma-exciting the elemental gas constituted by a single element, and supplying the elemental gas containing the active species X to the wafer 200; and (c) forming a second layer by generating an active species Y (also referred to as a second active species) by plasma-exciting the reactive gas containing nitrogen (N) and supplying the reactive gas containing the active species Y to the wafer 200. For example, (b) may further include generating an active species Z (also referred to as a third active species) by plasma-exciting a compound gas constituted by a plurality of elements and supplying the compound gas containing the active species Z to the wafer 200. Further, in (b), a ratio of a supply amount of the compound gas to a supply amount of the elemental gas is set to be lower than ½.

In an example of the film forming sequence shown in FIG. 4, the ratio of the supply amount of the compound gas to the supply amount of the elemental gas is set to be lower than ½ by setting a ratio of a supply flow rate of the compound gas to a supply flow rate of the elemental gas to be lower than ½. In addition, it is preferable that the ratio of the supply amount of the compound gas to the supply amount of the elemental gas is set to be ⅓ or lower. Further, in FIG. 4, “1st cycle” indicates a first execution of the cycle, “2nd cycle” indicates a second execution of the cycle, and “n^{th} cycle” indicates an n^{th} execution of the cycle.

Further, in the example of the film forming sequence shown in FIG. 4, in (b), the active species X and the active species Z generated by plasma-exciting the elemental gas and the compound gas, respectively, are supplied to the wafer 200. In addition, in (c), the active species Y generated by plasma-exciting the reactive gas is supplied to the wafer 200.

In the present specification, such a film forming sequence of the substrate processing described above may be illustrated as follows. Film forming sequences of modified examples and other embodiments (which will be described later) will be also represented in the same manner.
(Source gas→Plasma-excited elemental gas & Plasma-excited compound gas→Plasma-excited reactive gas)×n

In the film forming sequence shown in FIG. 4, it is preferable to perform a vacuum exhaust after (a) and after (c). In such a case, the film forming sequence may be represented as follows.
(Source gas→Purge→Plasma-excited elemental gas & Plasma-excited compound gas→Plasma-excited reactive gas→Purge)×n

In the present disclosure, the film containing the predetermined element and nitrogen may include not only a nitride film (SiN film) containing the predetermined element such as silicon (Si) but also a nitride film containing carbon (C) and oxygen (O). For example, the nitride film may include a film such as a silicon nitride film (SiN film), a silicon carbonitride film (SiCN film), a silicon oxynitride film (SiON film) and a silicon oxycarbonitride film (SiOCN film). The present embodiments will be described by way of an example in which silicon is used as the predetermined element, and the SiN film is formed as a film containing silicon and nitrogen.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

### <Wafer Charging Step and Boat Loading Step>

The wafers 200 are charged (transferred) into the boat 217 (wafer charging step). Thereafter, as shown in FIG. 1, the boat 217 supporting the wafers 200 is elevated by the boat elevator 115 and thereby loaded (transferred) into the process chamber 201 (boat loading step). With the boat 217 loaded, the seal cap 219 airtightly seals the lower end of the reaction tube 203 via the O-ring 220b.

### <Pressure Adjusting Step and Temperature Adjusting Step>

After the boat loading step is completed, the vacuum pump 246 vacuum-exhausts (decompresses and exhausts) the inner atmosphere of the process chamber 201 (that is, a space in which the wafers 200 are present (accommodated)) such that the inner pressure of the process chamber 201 reaches and is maintained at a desired pressure (vacuum level). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245 (pressure adjusting step). In addition, the heater 207 heats the process chamber 201 such that a temperature of the wafer 200 in the process chamber 201 reaches and is maintained at a desired process temperature. When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained (temperature adjusting step). In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

### <Gas Charging Step>

Thereafter, with the valve 242a closed, the valve 243a is opened to supply the source gas into the gas supply pipe 232a. After a flow rate of the source gas is adjusted by the MFC 241a, the source gas whose flow rate is adjusted is stored in an inner portion (hereinafter, also referred to as the “gas storage”) of the gas supply pipe 232a between the valves 243a and 242a. Thereby, it is possible to charge (fill or store) the source gas in the gas storage. When a predetermined amount of the source gas has been filled into the gas storage, the valve 243a is closed such that a state in which the source gas is charged in the gas storage can be maintained.

### <Film Forming Process>

Thereafter, a film forming process is performed by sequentially performing a step A, a step B and a step C described below.

### <Step A>

In the step A, the source gas is supplied onto the wafer 200 in the process chamber 201.

Specifically, the valve 242a is opened to supply the source gas charged in the gas storage in a high pressure state into the process chamber 201 at once (that is, in a pulse-wise manner) via the gas supply pipe 232a and the nozzle 249a. Hereinafter, such a supply method mentioned above may also be referred to as a “flash flow”. When supplying the source gas, the valves 243d, 243e and 243g are opened to supply the inert gas into the process chamber 201 through each of the nozzles 249a to 249c. Further, in some of methods described below, the inert gas may not be supplied. In addition, the present step is preferably performed with the exhauster substantially fully closed (that is, with the APC valve 244 substantially fully closed). When the APC valve 244 is closed, the inner pressure of the process chamber 201 is elevated rapidly to a predetermined pressure. Thereafter, a boosted state (elevated state) in the process chamber 201 is maintained for a predetermined time, and the wafer 200 is exposed to an atmosphere containing the source gas in a high pressure state.

For example, process conditions in the present step are as follows:
A process temperature: from 250° C. to 600° C., preferably from 300° C. to 600° C.;
A process pressure (before the flash flow): from 30 Pa to 600 Pa;
A process pressure (after the flash flow): from 500 Pa to 1,500 Pa;
A supply amount of the source gas (for R1): from 120 cc to 360 cc, preferably from 120 cc to 240 cc;
An exposure time (time duration) of the source gas: from 1 second to 20 seconds, preferably from 5 seconds to 10 seconds; and
A supply flow rate of the inert gas (for each of R1, R2 and R3): from 0 slm to 10 slm, preferably from 0 slm to 5 slm.

Further, in the present specification, a notation of a numerical range such as “from 250° C. to 600° C.” means that a lower limit and an upper limit are included in the numerical range. Therefore, for example, a numerical range “from 250° C. to 600° C.” means a range equal to or higher than 250° C. and equal to or lower than 600° C. The same also applies to other numerical ranges described in the present specification. Further, in the present specification, the process temperature may refer to the temperature of the wafer 200 or the inner temperature of the process chamber 201, and the process pressure may refer to the inner pressure of the process chamber 201. In addition, when a supply flow rate of a gas is zero (0) sccm, it refers to a case where the gas is not supplied. The same also applies to the following descriptions.

By supplying the source gas (for example, a chlorosilane-based gas) to the wafer 200 in accordance with the process conditions described above, a silicon-containing layer (serving as a first layer) containing chlorine (Cl) is formed on an uppermost surface of the wafer 200 serving as a base. For example, the silicon-containing layer containing chlorine may be formed by a physical adsorption or a chemical adsorption of molecules of the chlorosilane-based gas onto the uppermost surface of the wafer 200, a physical adsorption or a chemical adsorption of molecules of substances generated by decomposing a part of the chlorosilane-based gas onto the uppermost surface of the wafer 200, a deposition of silicon onto the uppermost surface of the wafer 200 due to a thermal decomposition of the chlorosilane-based gas and the like. That is, the silicon-containing layer containing chlorine may be an adsorption layer (a physical adsorption layer or a chemical adsorption layer) of the molecules of the chlorosilane-based gas or the molecules of the substances generated by decomposing a part of the chlorosilane-based gas, or may be a deposition layer of silicon containing chlorine. In the present specification, the silicon-containing layer containing chlorine may also be simply referred to as a “silicon-containing layer”.

When the process temperature is set to be lower than 250° C., it may be difficult to adsorb silicon onto the wafer 200. Thereby, it may be difficult to form the first layer. By setting the process temperature to be 250° C. or higher, it is possible to form the first layer on the wafer 200. By setting the process temperature to be 300° C. or higher, it is possible to more sufficiently form the first layer on the wafer 200.

When the process temperature is set to be higher than 600° C., for example, the chlorosilane-based gas serving as the source gas may be thermally decomposed, and silicon may be deposited in a plurality of layers on the wafer 200. Thereby, it may be difficult to form the first layer with a substantially uniform thickness of less than one atomic layer. By setting the process temperature to be 600° C. or lower, it is possible to form the first layer with the substantially uniform thickness of less than one atomic layer, and it is also possible to improve a thickness uniformity of the film within a surface of the wafer 200. In the present specification, the term “a layer with a thickness of less than one atomic layer” may refer to an atomic layer formed discontinuously, and the term “a layer with a thickness of one atomic layer” may refer to an atomic layer formed continuously. In addition, when the layer with the thickness of less than one atomic layer is substantially uniform, it means that atoms are adsorbed on the surface of the wafer 200 with a substantially uniform density.

By supplying the source gas (for example, the chlorosilane-based gas) to the wafer 200 in accordance with the process conditions described above, it is possible to form the first layer containing chlorine the wafer 200. Further, it is possible to set a chlorine concentration in the first layer formed on an outer periphery of the wafer 200 to be substantially the same as a chlorine concentration in the first layer formed on a central portion of the wafer 200. Herein, “the chlorine concentrations are substantially the same” may refer to not only a case where the chlorine concentrations are exactly the same but also a case where the chlorine concentrations are approximately the same within a predetermined error range. For example, the predetermined error range may correspond to a ratio of the chlorine concentrations at the outer periphery and the central portion of the wafer 200, that is, (the chlorine concentration at the outer periphery)/(the chlorine concentration at the central portion), falls within a range from 0.80 to 1.20.

After the first layer is formed, the valve 242a is closed to stop a supply of the source gas into the process chamber 201. Then, for example, the APC valve 244 is fully opened to vacuum-exhaust the inner atmosphere of the process chamber 201. Thereby, it is possible to remove a substance such as a residual gas remaining in the process chamber 201 from the process chamber 201 (purge operation). When purging the process chamber 201, with the valves 243d, 243e and 243g open, the inert gas is continuously supplied into the process chamber 201. The inert gas supplied through each of the nozzles 249a to 249c acts as the purge gas, and thereby the process chamber 201 is purged (purge operation).

For example, process conditions in the purge operation are as follows:
A process temperature: from 250° C. to 600° C., preferably 300° C. to 600° C.;
A process pressure: from 1 Pa to 70 Pa, preferably 1 Pa to 30 Pa;
A supply flow rate of the inert gas (for each of R1, R2 and R3): from 0.05 slm to 20 slm, preferably from 1 slm to 5 slm; and
A supply time (time duration) of the inert gas: from 1 second to 20 seconds, preferably from 1 second to 10 seconds.

As the source gas, for example, a silane-based gas containing silicon (Si) serving as a main element (primary element) constituting the film to be formed on the wafer 200 may be used. As the silane-based gas, for example, a gas containing silicon and the halogen element, that is, a halosilane-based gas may be used. The halogen element includes an element such as chlorine (Cl), fluorine (F), bromine (Br) and iodine (I). As the halosilane-based gas, for example, the chlorosilane-based gas containing silicon and chlorine mentioned above may be used.

As the source gas, for example, the chlorosilane-based gas such as dichlorosilane (SiH₂Cl₂, abbreviated as DCS) gas, monochlorosilane (SiH₃Cl, abbreviated as MCS) gas, trichlorosilane (SiHCl₃, abbreviated as TCS) gas, tetrachlorosilane (SiCl₄, abbreviated as 4CS) gas, hexachlorodisilane (Si₂Cl₆, abbreviated as HCDS) gas and octachlorotrisilane (Si₃Cl₈, abbreviated as OCTS) gas may be used. For example, one or more of the gases exemplified above as the chlorosilane-based gas may be used as the source gas.

As the inert gas, for example, nitrogen (N₂) gas or a rare gas such as argon (Ar) gas, helium (He) gas, neon (Ne) gas and xenon (Xe) gas may be used. For example, one or more of the gases exemplified above as the inert gas may be used as the inert gas. The same also applies to each step described later.

### <Step B>

After the step A is completed, the elemental gas and the compound gas (which are plasma-excited) are supplied onto the wafer 200 in the process chamber 201, that is, the first layer (silicon-containing layer) formed on the wafer 200.

Specifically, with the APC valve 244 open, that is, with the process chamber 201 exhausted, the valves 243b and 243f are opened to supply the elemental gas and the compound gas into the gas supply pipes 232b and 232c, respectively. After flow rates of the elemental gas and the compound gas are adjusted by the MFCs 241b and 241f, respectively, the elemental gas and the compound gas whose flow rates are adjusted are supplied into the process chamber 201 through the nozzles 249b and 249c, respectively, and are exhausted through the exhaust port 231a. In the present step, thereby, the elemental gas and the compound gas are supplied to the wafer 200 through a side portion of the wafer 200 (that is, from an outer edge of the wafer 200 toward the center of the wafer 200) (elemental gas and compound gas supply). In addition, with the valves 243d, 243e and 243g open, the inert gas is continuously supplied into the process chamber 201.

Further, in the present step, by applying the RF power to the plasma generation electrodes, the elemental gas and the compound gas supplied into the gas supply pipes 232b and 232c are plasma-excited in the remote plasma units 300b and 300c, respectively. Thereby, the active species X is generated from the elemental gas and the active species Z is generated from the compound gas. The elemental gas containing the active species X and the compound gas containing the active species Z generated in a manner described above are supplied to the wafer 200 (plasma-excited elemental gas and compound gas supply).

For example, when hydrogen (H₂) gas is used as the elemental gas constituted by a single element, the H₂ gas is plasma-excited to generate the active species X such as H₂*, and the active species X is supplied to the wafer 200. In the present specification, the symbol “*” refers to a radical. The same also applies to the following descriptions.

For example, when a hydrogen nitride-based gas containing nitrogen (N) and hydrogen (H) is used as the compound gas constituted by a plurality of elements, the hydrogen nitride-based gas is plasma-excited to generate the active species Z such as NH₃*, and the active species Z is supplied to the wafer 200.

For example, process conditions of the present step are as follows:
A process temperature: from 250° C. to 600° C., preferably from 300° C. to 600° C.;
A process pressure: from 1 Pa to 100 Pa, preferably from 1 Pa to 50 Pa;
A supply flow rate of the elemental gas: from 0.1 slm to 3.0 slm, preferably from 0.2 slm to 1.0 slm;
A supply time (time duration) of the elemental gas: from 5 seconds to 60 seconds, preferably from 5 seconds to 20 seconds;
A supply flow rate of the compound gas: from 0.05 slm to 1.0 slm, preferably from 0.1 slm to 0.5 slm;
A supply time (time duration) of the compound gas: from 5 seconds to 60 seconds, preferably from 5 seconds to 20 seconds;
A supply flow rate of the inert gas (for each of R1, R2 and R3): from 0 slm to 10 slm, preferably from 0 slm to 1.5 slm; and
The high frequency power (RF power): from 50 W to 1,000 W, preferably from 50 W to 300 W.

By supplying the elemental gas and the compound gas (which are plasma-excited) to the wafer 200 in accordance with the process conditions described above, the first layer (silicon-containing layer) formed on the surface of the wafer 200 in the step A is modified such that chlorine (which is the halogen element) is desorbed from the first layer. Further, for example, a part of the first layer is modified to be nitrided. In a manner described above, a layer obtained by modifying the first layer (hereinafter, also referred to as a “modified layer”) is formed on the surface of the wafer 200. Hereinafter, details thereof will be described.

By plasma-exciting the elemental gas and supplying the elemental gas containing the active species X to the wafer 200 under the above-described conditions, it is possible to desorb chlorine from the first layer formed on the wafer 200.

However, when the elemental gas is supplied through the side portion of the wafer 200, the active species X supplied into the process chamber 201 flows from the outer periphery of the wafer 200 toward the central portion of the wafer 200. The active species X (for example, the H₂*) supplied into the process chamber 201 in a manner described above tends to be consumed (discharged) by combining with a substance such as chlorine on the first layer formed on the outer periphery of the wafer 200, and is less likely to reach the central portion of the wafer 200. Therefore, an intensity of desorption of chlorine at the central portion of the wafer 200 is weaker (lower) than an intensity of the desorption of chlorine at the outer periphery of the wafer 200, and the chlorine concentration at the central portion of the wafer 200 may be higher than the chlorine concentration at the outer periphery of the wafer 200.

Therefore, in the present step, the compound gas (which is plasma-excited) is supplied through the side portion of the wafer 200 such that the supply amount (that is, the supply flow rate in the present embodiment) thereof is set to be lower than ½ the supply amount (that is, the supply flow rate in the present embodiment) of the elemental gas (which is plasma-excited). Under such conditions, the active species Z supplied into the process chamber 201 flows from the outer periphery of the wafer 200 toward the central portion of the wafer 200. Since the supply amount of the compound gas in the present step is set to be smaller than the supply amount of the elemental gas, the active species Z (for example, the NH₃*) supplied into the process chamber 201 is consumed by combining with a substance such as silicon on the first layer formed on the outer periphery of the wafer 200, and hardly reaches the central portion of the wafer 200. Therefore, it is possible to set an intensity of inhibiting the desorption of chlorine at the outer periphery of the wafer 200 to be stronger than an intensity of inhibiting the desorption of chlorine at the central portion of the wafer 200. Thus, it is possible to set the intensity of the desorption of chlorine at the outer periphery of the wafer 200 due to the active species X to be substantially the same as the intensity of the desorption of chlorine at the central portion of the wafer 200, and it is also possible to set the chlorine concentration at the outer periphery of the wafer 200 to be substantially the same as the chlorine concentration at the central portion of the wafer 200. Herein, “the chlorine concentrations are substantially the same” may refer to not only a case where the chlorine concentrations are exactly the same but also a case where the chlorine concentrations are approximately the same within a predetermined error range. For example, the predetermined error range may correspond to a ratio of the chlorine concentrations at the outer periphery and the central portion of the wafer 200, that is, (the chlorine concentration at the outer periphery)/(the chlorine concentration at the central portion), falls within a range from 0.80 to 1.20.

In addition, it is considered that, since it is possible to prevent (or inhibit) the active species X from reaching the first layer by adsorbing the active species Z with a three-dimensional structure (steric structure) to the surface of wafer 200 or by adsorbing the active species Z with a polarity to the surface of wafer 200, it is possible to inhibit (or hinder) the desorption of chlorine from the first layer by supplying the active species Z to the wafer 200.

In a case where the ratio of the supply amount of the compound gas (which is plasma-excited) to the supply amount of the elemental gas (which is plasma-excited) is set to be ½ or more, when the active species Z is supplied, an amount of the active species Z reaching the central portion of the wafer 200 may be equal to or greater than an amount of the active species Z that enables obtaining an effect of inhibiting the desorption of chlorine. Thereby, the desorption of chlorine may be inhibited over almost the entire surface of the first layer. That is, in the case where the ratio of the supply amount of the compound gas (which is plasma-excited) to the supply amount of the elemental gas (which is plasma-excited) is set to be ½ or more, an effect of desorbing chlorine obtained by supplying the active species X may be suppressed over the entire surface of the wafer 200, and thereby, the effect of desorbing chlorine by the active species X may not be sufficiently obtained. By setting the ratio of the supply amount of the compound gas (which is plasma-excited) to the supply amount of the elemental gas (which is plasma-excited) to be lower than ½, it is possible to restrict the active species Z from reaching the central portion of the wafer 200. Thereby, it is possible to obtain the effect of inhibiting the desorption of chlorine by the active species Z at the outer periphery of the wafer 200 while maintaining the effect of desorbing chlorine by the active species X at the central portion of the wafer 200.

When the process temperature is set to be lower than 250° C., it may be difficult for a reaction of desorbing chlorine by the active species X to occur. By setting the process temperature to be 250° C. or higher, it is possible to promote the reaction of desorbing chlorine by the active species X. By setting the process temperature to be 300° C. or higher, it is possible to more reliably proceed with the reaction of desorbing chlorine by the active species X.

When the process temperature is set to be higher than 600° C., it may be difficult for a reaction of inhibiting the desorption of chlorine by the active species Z to occur. By setting the process temperature to be 600° C. or lower, it is possible to promote the reaction of inhibiting the desorption of chlorine by the active species Z.

After the modified layer is formed on the wafer 200, an application of the RF power to the plasma generation electrodes is stopped, and the valves 243b and 243f are closed to stop a supply of the elemental gas and a supply of the compound gas into the process chamber 201. When stopping the supply of the elemental gas and the supply of the compound gas, with the valves 243d, 243e and 243g open, the inert gas is continuously supplied into the process chamber 201.

As the elemental gas, for example, instead of or in addition to the H₂ gas described above, the nitrogen (N₂) gas or a rare gas such as argon (Ar) gas and helium (He) gas may be used. For example, one or more of the gases exemplified above as the elemental gas may be used as the elemental gas.

For example, when the N₂ gas is used as the elemental gas, the N₂ gas is plasma-excited to generate the active species X such as N* and N₂*. For example, when the argon (Ar) gas is used as the elemental gas, the Ar gas is plasma-excited to generate the active species X such as Ar*. For example, when the helium (He) gas is used as the elemental gas, the He gas is plasma-excited to generate the active species X such as He*.

As the compound gas, for example, the hydrogen nitride-based gas such as ammonia (NH₃) gas, diazene (N₂H₂) gas, hydrazine (N₂H₄) gas and N₃H₈ gas may be used. For example, one or more of the gases exemplified above as the compound gas may be used as the compound gas.

For example, when the hydrogen nitride-based gas is used as the compound gas, the hydrogen nitride-based gas is plasma-excited to generate the active species Z such as NH*, NH₂* and NH₃*.

### <Step C>

After the step B is completed, the reactive gas (which is plasma-excited) is supplied onto the wafer 200 in the process chamber 201, that is, the modified layer formed on the wafer 200. Further, in the present embodiments, a purge operation for the process chamber 201 is not performed between the step B and the step C.

Specifically, with the APC valve 244 open, that is, with the process chamber 201 exhausted, the valve 243c is opened to supply the reactive gas into the gas supply pipe 232c. After a flow rate of the reactive gas is adjusted by the MFC 241c, the reactive gas whose flow rate is adjusted is supplied into the process chamber 201 through the nozzle 249c, and is exhausted through the exhaust port 231a. In the present step, thereby, the reactive gas is supplied to the wafer 200 through the side portion of the wafer 200 (reactive gas supply). In addition, with the valves 243d, 243e and 243g open, the inert gas is continuously supplied into the process chamber 201.

Further, in the present step, by applying the RF power to the plasma generation electrodes, the reactive gas supplied into the gas supply pipe 232c is plasma-excited in the remote plasma unit 300c. Thereby, the active species Y is generated from the reactive gas. The reactive gas containing the active species Y generated in a manner described above is supplied to the wafer 200 (plasma-excited reactive gas supply).

For example, when a hydrogen nitride-based gas containing nitrogen (N) and hydrogen (H) is used as the reactive gas, the hydrogen nitride-based gas is plasma-excited to generate the active species Y such as NH*, NH₂* and NH₃*, and the active species Y is supplied to the wafer 200.

For example, process conditions of the present step are as follows:
A process temperature: from 250° C. to 600° C., preferably from 300° C. to 600° C.;
A process pressure: from 1 Pa to 100 Pa, preferably from 1 Pa to 50 Pa;
A supply flow rate of the reactive gas: from 0.1 slm to 10 slm, preferably from 0.5 slm to 5.0 slm;
A supply time (time duration) of the reactive gas: from 1 second to 60 seconds, preferably from 10 seconds to 40 seconds;
A supply flow rate of the inert gas (for each of R1, R2 and R3): from 0 slm to 10 slm, preferably from 0 slm to 1.5 slm; and
The high frequency power (RF power): from 50 W to 1,000 W, preferably from 50 W to 300 W.

By supplying the reactive gas to the wafer 200 in accordance with the process conditions described above, at least a part of the modified layer formed on the surface of the wafer 200 in the step B is nitrided (modified). As a result, a silicon nitride layer (SiN layer) containing silicon and nitrogen is formed as the second layer on the surface of the wafer 200. When the second layer is formed, impurities such as chlorine contained in the modified layer form a gaseous substance containing at least chlorine during a process of a modification reaction by the reactive gas (which is plasma-excited), and are discharged from the process chamber 201. Thereby, the second layer contains fewer impurities such as chlorine as compared with the modified layer formed in the step B.

When the process temperature is set to be lower than 250° C., it may be difficult for the reactive gas to decompose thermally. Thereby, it may be difficult to form the second layer. By setting the process temperature to be 250° C. or higher, it is possible to form the second layer. By setting the process temperature to be 300° C. or higher, it is possible to more reliably form second layer.

When the process temperature is set to be higher than 600° C., a thermal decomposition of the reactive gas may be excessive, and thereby, it may be difficult to form the second layer. By setting the process temperature to be 600° C. or lower, it is possible to suppress an excessive thermal decomposition of the reactive gas, and thereby it is possible to form the second layer.

After the second layer is formed on the wafer 200, an application of the RF power to the plasma generation electrodes is stopped, and the valve 243c is closed to stop a supply of the reactive gas into the process chamber 201. Then, a substance such as a residual gas remaining in the process chamber 201 is removed from the process chamber 201 in substantially the same process procedures and the same process conditions as in the purge operation of the step A described above.

As the reactive gas, for example, the hydrogen nitride-based gas such as the NH₃ gas, the N₂H₂ gas, the N₂H₄ gas and the N₃H₈ gas may be used. For example, one or more of the gases exemplified above as the reactive gas may be used as the reactive gas.

As the reactive gas, for example, instead of the hydrogen nitride-based gas exemplified above, a gas containing nitrogen (N), carbon (C) and hydrogen (H) may be used. For example, as the gas containing nitrogen, carbon and hydrogen, an amine-based gas or an organic hydrazine-based gas may be used. The gas containing nitrogen, carbon and hydrogen may serve as a gas containing nitrogen, a gas containing carbon, a gas containing hydrogen, or a gas containing nitrogen and carbon.

As the reactive gas, for example, an ethylamine-based gas such as monoethylamine (C₂H₅NH₂, abbreviated as MEA) gas, diethylamine ((C₂H₅)₂NH, abbreviated as DEA) gas and triethylamine ((C₂H₅)₃N, abbreviated as TEA) gas, a methylamine-based gas such as monomethylamine (CH₃NH₂, abbreviated as MMA) gas, dimethylamine ((CH₃)₂NH, abbreviated as DMA) gas and trimethylamine ((CH₃)₃N, abbreviated as TMA) gas, or an organic hydrazine-based gas such as monomethylhydrazine ((CH₃)HN₂H₂, abbreviated as MMH) gas, dimethylhydrazine ((CH₃)₂N₂H₂, abbreviated as DMH) gas, trimethylhydrazine ((CH₃)₂N₂(CH₃)H, abbreviated as TMH) gas may be used. For example, one or more of the gases exemplified above as the reactive gas may be used as the reactive gas. Further, the reactive gas may be the same as the compound gas, or may be different from the compound gas. When the same gas is used as the reactive gas and the compound gas, the active species Z and the active species Y may be the same active species.

### <Performing Cycle Predetermined Number of Times>

By performing the cycle wherein the step A, the step B and the step C described above are performed non-simultaneously (that is, in a non-synchronized manner) in this order a predetermined number of times (n times, wherein n is an integer of 1 or more), it is possible to form the silicon nitride film (SiN film) on the surface of the wafer 200. It is preferable that the cycle described above is repeatedly performed a plurality of times. That is, it is preferable that the cycle is repeatedly performed a plurality of times until a thickness of a stacked film formed by the SiN film reaches a desired thickness while a thickness of the SiN layer formed per each cycle is smaller than the desired thickness.

In the step B described above, by desorbing chlorine from the first layer, it is possible to reduce a wet etching rate (WER) of the SiN film formed by repeatedly performing the cycle described above.

In the step B described above, by setting the chlorine concentration at the outer periphery of the wafer 200 to be (substantially) the same as the chlorine concentration at the central portion of the wafer 200, it is possible to set the WER of the SiN film (which is formed by repeatedly performing the cycle described above) at a central portion to be substantially the same as that at an outer periphery of the SiN film. Thereby, it is possible to improve a uniformity (hereinafter, also simply referred to as a “uniformity within the surface of the wafer 200”) of wet etching for the SiN film. In other words, by setting properties of the SiN film at the central portion thereof to be substantially the same as that at the outer periphery thereof, it is possible to improve a uniformity of the properties of the SiN film within the surface of the wafer 200.

### <After-purge Step and Returning to Atmospheric Pressure Step>

After a process of forming the nitride film of the desired thickness on the wafer 200 is completed, the inert gas serving as the purge gas is supplied into the process chamber 201 through each of the nozzles 249a, 249b and 249c, and then is exhausted through the exhaust port 231a. Thereby, the inner atmosphere of the process chamber 201 is purged with the purge gas. As a result, a substance such as a residual gas remaining in the process chamber 201 and reaction by-products remaining in the process chamber 201 can be removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### <Boat Unloading Step and Wafer Discharging Step>

Thereafter, the seal cap 219 is lowered by the boat elevator 115 and the lower end of the reaction tube 203 is opened. Then, the boat 217 with the wafers 200 (which are processed) supported therein is unloaded (transferred) out of the reaction tube 203 through the lower end of the reaction tube 203 (boat unloading step). After the boat 217 is unloaded, the wafers 200 (which are processed) are discharged (transferred) from the boat 217 (wafer discharging step).

### (3) Effects According to Present Embodiments

According to the present embodiments, it is possible to obtain one or more of the following effects.

(a) By supplying the elemental gas in the step B, it is possible to desorb chlorine from the first layer by the active species X. Thereby, it is possible to densify the first layer, and thereby it is possible to finalize the film formation of a film on the wafer 200 (for example, the SiN film) whose WER is low. Further, by supplying the compound gas in the step B, it is possible for the active species Z to inhibit the desorption of chlorine from the first layer, and thereby it is possible to control a distribution of the intensity of the desorption of chlorine by the active species X within the surface of the wafer 200.

Further, by setting the ratio of the supply amount of the compound gas to the supply amount of the elemental gas to be lower than ½ in the step B, under a situation in which the intensity of the desorption of chlorine at the outer periphery of the wafer 200 is stronger than the intensity of the desorption of chlorine at the central portion of the wafer 200, it is possible to set the intensity of inhibiting the desorption of chlorine at the outer periphery of the wafer 200 to be stronger than the intensity inhibiting the desorption of chlorine at the central portion of the wafer 200. Thereby, after the step B is performed, it is possible to set the chlorine concentration in the first layer at the outer periphery of the wafer 200 to be substantially the same as the chlorine concentration in the first layer at the central portion of the wafer 200. As a result, it is possible to set the WER of the film finally formed on the wafer 200 at a central portion thereof to be substantially the same as that at an outer periphery thereof, and thereby making it possible to finalize the formation of the film on the wafer 200 whose uniformity of the WER is excellent within the surface of the wafer 200. As a result, it is possible to form the film whose WER is low and whose uniformity of the WER is excellent within the surface of the wafer 200. In other words, it is possible to form the film whose properties are excellent and whose uniformity of the properties is excellent within the surface of the wafer 200.

(b) In addition, by setting the ratio of the supply amount of the compound gas to the supply amount of the elemental gas to be equal to or lower than ⅓ in the step B, it is possible to reliably form the film whose WER is low and whose uniformity of the WER is excellent within the surface of the wafer 200. When the ratio of the supply amount of the compound gas to the supply amount of the elemental gas is set to be higher than ⅓, it may not be possible to sufficiently reduce chlorine concentration, particularly at the central portion of the wafer 200. Thereby, it may not be possible to obtain a desired uniformity of the WER within the surface of the wafer 200.

(c) By setting the ratio of the supply amount of the compound gas to the supply amount of the elemental gas to be lower than ½ in the step B, even when the process temperature in each of the steps A to C is set to be a relatively low temperature within a range from 250° C. to 600° C., it is possible to form the film whose WER is low and whose uniformity of the WER is excellent within the surface of the wafer 200. Since the process temperature in each of the steps A to C can be set to be a relatively low temperature, it is possible to reduce damages to the process furnace 202 or the wafer 200.

(d) By setting the ratio of the supply amount of the compound gas to the supply amount of the elemental gas to be lower than ½ in the step B, even when the wafer 200 is processed by using a so-called vertical type process furnace in which the elemental gas and the compound gas are supplied through the side portion of the wafer 200, it is possible to form the film whose WER is low and whose uniformity of the WER is excellent within the surface of the wafer 200. In addition, since a batch and vertical type process furnace capable of simultaneously processing a plurality of wafers 200 can be used, it is possible to improve a productivity of the film forming process.

### Other Embodiments of Present Disclosure

While the technique of the present disclosure is described in detail by way of the embodiments mentioned above, the technique of the present disclosure is not limited thereto. The technique of the present disclosure may be modified in various ways without departing from the scope thereof.

For example, the embodiments mentioned above are described by way of an example in which the silicon nitride film is used. However, the technique of the present disclosure is not limited thereto. For example, the technique of the present disclosure may be preferably applied to form a nitride film (metal nitride film) containing a metal element such as titanium (Ti), zirconium (Zr), hafnium (Hf), tantalum (Ta), niobium (Nb), molybdenum (Mo), tungsten (W), yttrium (Y), strontium (Sr), lanthanum (La), ruthenium (Ru) and aluminum (Al) as a main element (primary element).

For example, the technique of the present disclosure may be preferably applied to form a metal nitride film such as a titanium nitride film (TiN film), a hafnium nitride film (HIN film), a tantalum nitride film (TaN film) and an aluminum nitride film (AlN film) on the wafer 200 using a gas such as titanium tetrachloride (TiCl₄) gas, hafnium tetrachloride (HfCl₄) gas, tantalum pentachloride (TaCl₅) gas, trimethylaluminum (Al(CH₃)₃, abbreviated as TMA) gas as the source gas in accordance with the following film forming sequences.
(TiCl₄→H₂*→NH₃*)×n⇒TiN
(HfCl₄→H₂*→NH₃*)×n⇒HfN
(TaCl₅→H₂*→NH₃*)×n⇒TaN
(TMA→H₂*→NH₃*)×n⇒AlN

Process procedures and process conditions of film forming processes of forming such films mentioned above may be substantially the same as those of the film forming process according to the embodiments or modified examples described above. Even in such a case, it is possible to obtain substantially the same effects as the embodiments or the modified examples described above. That is, the technique of the present disclosure may also be preferably applied to form a metalloid nitride film containing a metalloid element such as silicon as a main element (primary element) or to form a metal nitride film containing one or more of various metal elements described above as a main element (primary element).

For example, the embodiments mentioned above are described by way of an example in which the supply amount of the compound gas relative to the supply amount of the elemental gas in the step B is adjusted by adjusting the supply flow rate of the compound gas relative to the supply flow rate of the elemental gas. However, the technique of the present disclosure is not limited thereto. For example, the supply amount of the compound gas relative to the supply amount of the elemental gas in the step B may be adjusted by adjusting at least one among a partial pressure of the compound gas relative to a partial pressure of the elemental gas in the process chamber 201, a concentration of the compound gas relative to a concentration of the elemental gas in the process chamber 201, and the supply time of the compound gas relative to the supply time of the elemental gas in the process chamber 201. Specifically, by setting at least one among a ratio of the partial pressure of the compound gas to the partial pressure of the elemental gas, the ratio of the supply flow rate of the compound gas to the supply flow rate of the elemental gas, a ratio of the concentration of the compound gas to the concentration of the elemental gas, and a ratio of the supply time of the compound gas to the supply time of the elemental gas to be lower than ½, the ratio of the supply amount of the compound gas to the supply amount of the elemental gas can be set to be lower than ½. Even in such a case, it is possible to obtain substantially the same effects as the embodiments described above.

For example, the embodiments mentioned above are described by way of an example in which the supply of the elemental gas and the supply of the compound gas to the wafer 200 in the step B are started simultaneously and stopped simultaneously. However, the technique of the present disclosure is not limited thereto. For example, the supply of the compound gas may be started before the supply of the elemental gas is started, and then the elemental gas and the compound gas are supplied simultaneously. In addition, in a state in which the elemental gas and the compound gas are supplied simultaneously, the supply of the compound gas may be stopped before the supply of elemental gas is stopped, and then the supply of elemental gas is stopped. Even in such a case, it is possible to obtain substantially the same effects as the embodiments described above.

For example, the embodiments mentioned above are described by way of an example in which the elemental gas is plasma-excited in the remote plasma unit 300b and the compound gas is plasma-excited in the remote plasma unit 300c, respectively, and the active species X and the active species Z are individually supplied into the process chamber 201 through the nozzle 249b and the nozzle 249c, respectively. However, the technique of the present disclosure is not limited thereto. For example, the elemental gas and the compound gas may be mixed in a supply pipe, and then a gaseous mixture (mixed gas) of the elemental gas and the compound gas may be plasma-excited in a single remote plasma unit to generate the activate species X and the active species Z. In such a case, the gaseous mixture of the elemental gas and the compound gas containing the activate species X and the active species Z is supplied to the wafer 200.

For example, the embodiments mentioned above are described by way of an example in which the source gas is supplied in the step A by using the flash flow mentioned above. However, the technique of the present disclosure is not limited thereto. For example, the source gas may be supplied in the step A in substantially the same manner as a gas supply method in the steps B and C. Even in such a case, it is possible to obtain substantially the same effects as the embodiments described above.

It is preferable that recipes used in processes are prepared individually in accordance with contents of the processes and stored in the memory 121c via an electric communication line or the external memory 123. When starting each process, it is preferable that the CPU 121a selects an appropriate recipe among the recipes stored in the memory 121c in accordance with the contents of each process. Thus, various films of different composition ratios, qualities and thicknesses can be formed in a reliably reproducible manner by using a single substrate processing apparatus (that is, the substrate processing apparatus described above). In addition, since a burden on an operating personnel can be reduced, various processes can be performed quickly while avoiding an error in operating the substrate processing apparatus.

The recipe described above is not limited to creating a new recipe. For example, the recipe may be prepared by changing an existing recipe stored (or installed) in the substrate processing apparatus in advance. When changing the existing recipe to a new recipe, the new recipe may be installed in the substrate processing apparatus via the electric communication line or a recording medium in which the new recipe is stored. Further, the existing recipe already stored in the substrate processing apparatus may be directly changed to the new recipe by operating the input/output device 122 of the substrate processing apparatus.

For example, the embodiments described above are described by way of an example in which a substrate processing apparatus including a hot wall type process furnace is used to form the film. However, the technique of the present disclosure is not limited thereto. For example, the technique of the present disclosure may also be preferably applied when a substrate processing apparatus including a cold wall type process furnace is used to form the film.

The process procedures and the process conditions of each process using the substrate processing apparatuses described above may be substantially the same as those of the embodiments described above. Even in such a case, it is possible to obtain substantially the same effects as in the embodiments described above.

Further, the embodiments described above may be appropriately combined. The process procedures and the process conditions of each combination thereof may be substantially the same as those of the embodiments described above.

### Example of Embodiments

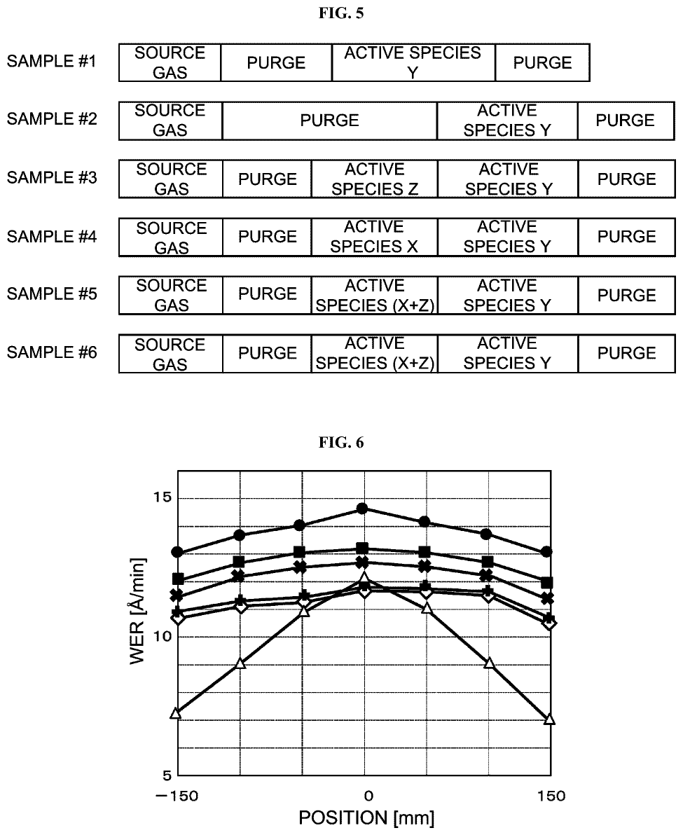

Using the substrate processing apparatus described above, the following film forming sequences are performed to form silicon nitride films (SiN films) on wafers. Thereby, sample #1 to #6 are prepared (see FIG. 5).
Sample #1: (Source gas→Purge→Plasma-excited reactive gas→Purge)×n
Sample #2: (Source gas→Purge→Plasma-excited reactive gas→Purge)×n
Sample #3: (Source gas→Purge→Plasma-excited compound gas→Plasma-excited reactive gas→Purge)×n
Sample #4: (Source gas→Purge→Plasma-excited elemental gas→Plasma-excited reactive gas→Purge)×n
Sample #5: (Source gas→Purge→Plasma-excited elemental gas & compound gas→Plasma-excited reactive gas→Purge)×n
Sample #6: (Source gas→Purge→Plasma-excited elemental gas & compound gas→Plasma-excited reactive gas→Purge)×n

FIG. 5 shows that the elemental gas, the reactive gas and the compound gas are excited to supply the active species X, the active species Y and the active species Z, respectively.

The DCS gas is used as the source gas, the H₂ gas is used as the elemental gas, the NH₃ gas is used as the compound gas and the reactive gas, and the N₂ gas is used as the inert gas. However, in the sample #6, the N₂ gas is used as the elemental gas.

The process conditions for performing each step of the example of the embodiments are set to be predetermined conditions within a range of the process conditions for each step shown in the embodiments described above. However, in the sample #2, a time duration (purge time) of performing the purge operation performed after the supply of the source gas is set to a long time of 30 seconds.

After the samples #1 to #6 are manufactured, the WER is measured at a plurality of predetermined locations of the SiN film formed on each wafer for each of the samples #1 to #6. FIG. 6 is a diagram schematically illustrating such measurement results.

A vertical axis shown in FIG. 6 indicates the WER (A/min) of the SiN film with respect to 1% hydrofluoric acid (1% HF aqueous solution). A horizontal axis shown in FIG. 6 indicates a predetermined position of the SiN film on the wafer whose diameter is 300 mm. For example, “−150” (in unit of mm) indicates one end of the diameter of the wafer, “0” (in unit of mm) indicates a midpoint of the diameter of the wafer (a center point of the wafer), and “150” (in unit of mm) indicates the other end of the diameter of the wafer. Further, the symbols “●”, “▪”, “x”, “Δ”, “⋄”, and “+” in FIG. 6 indicate the measurement results for the samples #1 to #6, respectively.

As shown in FIG. 6, it is confirmed that the WER of the sample #1 is the highest. Further, it is also confirmed that the WER of the sample #2 is the second highest and the WER of the sample #3 is the third highest. From these results, it is confirmed that the WER is not significantly reduced even when the purge time after the supply of the source gas is extended or even when the compound gas is supplied after the supply of the source gas.

In contrast, it is confirmed that the WER of the sample #4 is significantly reduced. From these results, it is confirmed that the WER can be reduced by supplying the elemental gas after supplying the source gas. On the other hand, it is confirmed that the WER within the surface of the wafer of the sample #4 is significantly different from those of the samples #1 to #3. Specifically, it is confirmed that a difference in the WER between the outer periphery and the central portion of the wafer is within 2 Å/min for the entirety of the samples #1 to #3, whereas it is about 5 Å/min for the sample #4. From these results, it is confirmed that, when the elemental gas (alone) is supplied after supplying the source gas, it is possible to reduce the WER, but the uniformity of the wet etching process within the surface of the wafer deteriorates.

It is confirmed that, in the sample #5, as compared with the samples #1 to #3, it is possible to reduce the WER and it is also possible to appropriately maintain the uniformity within the surface of the wafer. Specifically, it is confirmed that, it the sample #5, it is possible to maintain the difference in the WER between the outer periphery and the central portion of the wafer within 2 Å/min. From these results, it is confirmed that, by supplying both of the elemental gas and the compound gas after supplying the source gas, it is possible to reduce the WER, and it is also possible to appropriately maintain the uniformity within the surface of the wafer. Further, it is preferable that a ratio of the WER at the outer periphery to the WER at the central portion of the wafer is 0.80 or more and 1.20 or less.

It is also confirmed that, in the sample #6, it is possible to obtain results similar to those of the sample #5. From these results, it is confirmed that, even when the N₂ gas is used as the elemental gas, it is possible to obtain results similar to those of the sample #5.

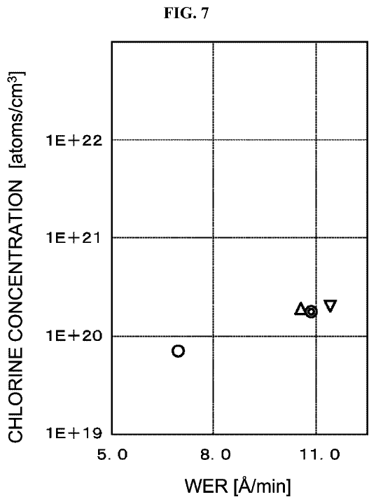

Further, after the samples #1 to #6 are manufactured, the WER and the chlorine concentration are measured at a plurality of predetermined locations of the SiN film formed on each wafer for each of the samples #4 and #5. FIG. 7 is a diagram schematically illustrating such measurement results.

A vertical axis shown in FIG. 7 indicates the chlorine concentration (atoms/cm³) in the SiN film. A horizontal axis shown in FIG. 7 indicates the WER (Å/min) of the SiN film with respect to 1% hydrofluoric acid (1% HF aqueous solution). Further, the symbols “∘”, “⊚”, “Δ” and “∇” in FIG. 7 indicate the WER and the chlorine concentration at the outer periphery of the wafer of the sample #4, the WER and the chlorine concentration at the central portion of the wafer of the sample #4, the WER and the chlorine concentration at the outer periphery of the wafer of the sample #5 and the WER and the chlorine concentration at the central portion of the wafer of the sample #5, respectively.

As shown in FIG. 7, it is confirmed that, in the sample #4, a difference in the chlorine concentration between the outer periphery and the central portion of the wafer is relatively large. In contrast, it is confirmed that, in the sample #5, a difference in the chlorine concentration between the outer periphery and the central portion of the wafer is relatively small.

Further, it is confirmed that, in the sample #4, the difference in the WER between the outer periphery and the central portion of the wafer is relatively large, that is, the uniformity within the surface of the wafer is poor. In contrast, it is confirmed that, in the sample #5, the difference in the WER between the outer periphery and the central portion of the wafer is relatively small, that is, the uniformity within the surface of the wafer is good.

From these results, it is confirmed that there is a correlation between a magnitude of the difference in the chlorine concentration between the outer periphery and the central portion of the wafer and a quality of the WER uniformity within the surface of the wafer, and that the smaller the difference in the chlorine concentration between the outer periphery and the central portion of the wafer, the better the WER uniformity within the surface of the wafer.

According to some embodiments of the present disclosure, it is possible to form the film on the substrate, wherein the uniformity of the properties of the film is excellent within the surface of the substrate.

What is claimed is:

1. A substrate processing method comprising:
forming a film containing a predetermined element and nitrogen on a substrate by performing a cycle a predetermined number of times,
wherein the cycle comprises:
(a) forming a first layer by supplying a source gas containing the predetermined element and a halogen element to the substrate;
(b) generating a first active species by plasma-exciting an elemental gas constituted by a single element and supplying the elemental gas containing the first active species to the substrate; and
(c) forming a second layer by generating a second active species by plasma-exciting a reactive gas containing nitrogen and supplying the reactive gas containing the second active species to the substrate,
wherein (b) comprises generating a third active species by plasma-exciting a compound gas constituted by a plurality of elements and supplying the compound gas containing the third active species to the substrate, and
wherein, in (b), a ratio of a supply amount of the compound gas to a supply amount of the elemental gas is set to be lower than ½.

2. The substrate processing method of claim 1, wherein, in (b), a ratio of a partial pressure of the compound gas to a partial pressure of the elemental gas is set to be lower than ½.

3. The substrate processing method of claim 1, wherein, in (b), a ratio of a concentration of the compound gas to a concentration of the elemental gas is set to be lower than ½.

4. The substrate processing method of claim 1, wherein, in (b), a ratio of a supply flow rate of the compound gas to a supply flow rate of the elemental gas is set to be lower than ½.

5. The substrate processing method of claim 1, wherein, in (b), a ratio of a supply time of the compound gas to a supply time of the elemental gas is set to be lower than ½.

6. The substrate processing method of claim 1, wherein, in (b), the third active species inhibits desorption of the halogen element from the first layer caused by the first active species.

7. The substrate processing method of claim 6, wherein, in (b), an intensity of inhibiting desorption of the halogen element at an outer periphery of the substrate by the third active species is set to be stronger than an intensity of inhibiting desorption of the halogen element at a central portion of the substrate by the third active species.

8. The substrate processing method of claim 7, wherein, when a wet etching is performed using hydrogen fluoride aqueous solution after (c) is performed, a ratio of a wet etching rate at the outer periphery to a wet etching rate at the central portion is set to be 0.80 or more and 1.20 or less.

9. The substrate processing method of claim 6, wherein, in (a), a concentration of the halogen element in the first layer formed at an outer periphery of the substrate before (b) is performed is set to be same as a concentration of the halogen element in the first layer formed at a central portion of the substrate before (b) is performed.

10. The substrate processing method of claim 6, wherein, in (b), a concentration of the halogen element in the first layer formed at an outer periphery of the substrate after (b) is performed is set to be lower than a concentration of the halogen element in the first layer formed at the outer periphery before (b) is performed, and is set to be same as a concentration of the halogen element in the first layer formed at a central portion of the substrate after (b) is performed.

11. The substrate processing method of claim 1, wherein (a) to (c) are performed at a temperature of 250° C. or higher and 600° C. or lower.

12. The substrate processing method of claim 1, wherein the elemental gas comprises H₂ gas.

13. The substrate processing method of claim 1, wherein, in (b), the ratio of the supply amount of the compound gas to the supply amount of the elemental gas is set to be equal to or lower than ⅓.

14. The substrate processing method of claim 1, wherein both of the elemental gas and the compound gas are supplied to the substrate through a side portion of the substrate.

15. The substrate processing method of claim 1, wherein the source gas comprises a chlorosilane-based gas.

16. The substrate processing method of claim 1, wherein the compound gas comprises a hydrogen nitride-based gas, and the hydrogen nitride-based gas comprises one or both of ammonia gas and hydrazine gas.

17. The substrate processing method of claim 1, wherein, in (b), a distribution of a wet etching rate of the film within a surface of the substrate is adjusted based on a steric reaction hindrance by the compound gas or a desorption hindrance due to a polarity by the compound gas.

18. A method of manufacturing a semiconductor device, comprising:
the substrate processing method of claim 1.

19. A non-transitory computer-readable recording medium storing a program that causes a substrate processing apparatus, by a computer, to perform:
forming a film containing a predetermined element and nitrogen on a substrate by performing a cycle a predetermined number of times,
wherein the cycle comprises:
(a) forming a first layer by supplying a source gas containing the predetermined element and a halogen element to the substrate;
(b) generating a first active species by plasma-exciting an elemental gas constituted by a single element, and supplying the elemental gas containing the first active species to the substrate; and
(c) forming a second layer by generating a second active species by plasma-exciting a reactive gas containing nitrogen and supplying the reactive gas containing the second active species to the substrate,
wherein (b) comprises generating a third active species by plasma-exciting a compound gas constituted by a plurality of elements and supplying the compound gas containing the third active species to the substrate, and
wherein, in (b), a ratio of a supply amount of the compound gas to a supply amount of the elemental gas is set to be lower than ½.

20. A substrate processing apparatus comprising:
a source gas supplier configured to supply a source gas containing a predetermined element and a halogen element to a substrate;
an elemental gas supplier configured to supply an elemental gas constituted by a single element to the substrate;
a compound gas supplier configured to supply a compound gas constituted by a plurality of elements to the substrate;
a reactive gas supplier configured to supply a reactive gas containing nitrogen to the substrate;
an exciter configured to excite a gas supplied thereto; and
a controller configured to be capable of controlling the source gas supplier, the elemental gas supplier, the compound gas supplier, the reactive gas supplier and the exciter to perform:
forming a film containing the predetermined element and nitrogen on the substrate by performing a cycle a predetermined number of times,
wherein the cycle comprises:
(a) forming a first layer by supplying the source gas to the substrate;
(b) generating a first active species by plasma-exciting the elemental gas, and supplying the elemental gas containing the first active species to the substrate; and
(c) forming a second layer by generating a second active species by plasma-exciting the reactive gas and supplying the reactive gas containing the second active species to the substrate,
wherein (b) comprises generating a third active species by plasma-exciting the compound gas and supplying the compound gas containing the third active species to the substrate, and
wherein, in (b), a ratio of a supply amount of the compound gas to a supply amount of the elemental gas is set to be lower than ½.
